(19) United States
(12) Patent Application Publication
(10) Pub. No.: US 2007/0046359 A1
(43) Pub. Date: Mar. 1, 2007

(54) Apparatus and method for effecting switching of an input signal by a switching transistor

(75) Inventors: Alfio Zanchi, Colorado Springs, CO (US); Marco Corsi, Parker, TX (US)

Correspondence Address: TEXAS INSTRUMENTS INCORPORATED, P O BOX 655474, M/S 3999, DALLAS, TX, 75265, US

(73) Assignee: Texas Instruments Incorporated

(21) Appl. No.: 11/513,651

(22) Filed: Aug. 29, 2006

Related U.S. Application Data
(60) Provisional application No. 60/712,268, filed on Aug. 29, 2005.

(51) Int. Cl. H03K 17/16

(52) U.S. Cl. 327/390

(57) ABSTRACT

An apparatus switching an input signal by a switching transistor in response to a clock includes: (a) A capacitor. (b) A charging circuit coupled for charging the capacitor with a supply voltage in response to the clock. (c) A switching circuit coupled with the capacitor and configured for coupling the switching transistor with the capacitor in response to the clock. (d) A grounding circuit coupled with the switching transistor and a ground locus. The grounding circuit includes a first grounding transistor coupled with the switching transistor and a second grounding transistor. The first grounding transistor has connection loci permitting electrical coupling with the gate, the source, the drain and the bulk portion of the first grounding transistor. The source connection locus and the bulk connection locus are coupled in common. The second grounding transistor couples the first grounding transistor with the ground locus in response to the clock.

This application claims benefit of prior filed copending Provisional Patent Application Ser. No. 60/712,268, filed Aug. 29, 2005.

### BACKGROUND OF THE INVENTION

The present invention is directed to controlling the switching of signals when using a switching transistor, and especially to control operation of a sampling switch for switching a continuous-time analog input signal to present a sampled discrete-time analog output signal. The sampled discrete-time analog output signal is amendable to digitization by a quantizer. The present invention is particularly useful in analog-to-digital signal conversion devices using a switching transistor for switching an analog input signal to present a sampled discrete-time analog output signal for conversion to a digital signal.

One of the main design limitations affecting the harmonic distortion of circuits such as switched-capacitor circuits used for analog-to-digital signal conversion is represented by the non-linear resistance characteristic of the MOSFET (Metal Oxide Semiconductor Field Effect Transistor) devices employed as a signal switches. This circuit non-ideality is exacerbated by the general trend toward low-voltage supply, which further pushes transistors into an operating zone where their resistance is higher and also shows maximum variation with the voltage of the signal modulating the channel.

Sometimes the problem is circumvented by adoption of parallel connection of a PMOSFET (p-channel MOSFET) device and an NMOSFET (n-channel MOSFET) device, or transmission gate. Sometimes a simple pass transistor may be used, in order to limit parasitics especially in high-speed signal paths. In the latter instance, to counter the linearity limitation of such a pass transistor a widely adopted solution is the so-called “bootstrap” circuit. A bootstrap circuit uses the input signal to be gated or switched as a voltage reference above which the gate-driving voltage can be superimposed. This approach provides a constant VGS (Gate-to-Source Voltage) driving the MOSFET.

A representative bootstrap circuit has been proposed by Abo and Gray [Abo and Gray; “A 1.5 V, 10-Bit, 14.3 MS/s CMOS Pipeline Analog-to-Digital Converter”; IEEE Journal of Solid-State Circuits Vol. 34, No. 5; May 1999. pp. 599-606.]. This representative bootstrap circuit is substantially illustrated and described in FIG. 1 below.

In high-speed and high-resolution ADC (Analog-to-Digital Conversion) applications, as well as in every other instance when sampling of an analog signal is involved (i.e., optical receivers, data stream slicers, and similar circuits) any signal-dependent modulation of the switches' resistance as well as any signal-dependent charge injection introduced by the switches causes distortion. Even-order harmonics can be rejected by employing a differential front-end sampling. However, odd-order harmonic rejection relies on the linearity of the switch. From a 12-bit level accuracy on to greater accuracy levels, distortion requirements (rated via the Spurious-Free Dynamic Range; SFDR) are higher than 80 dBc. This level of distortion may be impacted by switch non-linearity alone. Moreover, some recent high-IF (Intermediate Frequency) sampling receiver architectures require linear handling of high-frequency channel signals, which is mainly achieved by first minimizing parasitics in the switches, such as by using a high voltage on the switch gate. Further, the high resolution required for converters providing 14-bit, 16-bit and higher accuracy must depend upon providing a high signal range in front of the ADC quantizer cell, meaning that the switch at the output of a Sample/Hold cell employed in such high resolution converters must handle ever higher signal peaks with increasing resolution.

There is a need for an apparatus and method for effecting switching of an input signal by a switching transistor providing improved distortion levels over prior art apparatuses and methods.

### SUMMARY OF THE INVENTION

An apparatus switching an input signal by a switching transistor in response to a clock includes: (a) A capacitor. (b) A charging circuit coupled for charging the capacitor with a supply voltage in response to the clock. (c) A switching circuit coupled with the capacitor and configured for coupling the switching transistor with the capacitor in response to the clock. (d) A grounding circuit coupled with the switching transistor and a ground locus. The grounding circuit includes a first grounding transistor coupled with the switching transistor and a second grounding transistor. The first grounding transistor has connection loci permitting electrical coupling with the gate, the source, the drain and the bulk portion of the first grounding transistor. The source connection locus and the bulk connection locus are coupled in common. The second grounding transistor couples the first grounding transistor with the ground locus in response to the clock.

A method for effecting switching of an input signal by a switching transistor device in response to a clock signal includes the steps of: (a) In no particular order: (1) providing a boosting capacitor; (2) providing a charging circuit coupled with a supply voltage and the boosting capacitor; (3) providing a switching circuit coupled with the boosting capacitor; and (4) providing a grounding circuit coupled with the switching transistor device and with a ground locus; the grounding circuit including a first grounding transistor device and a second grounding transistor device; the first grounding transistor device having a gate, a source, a drain and a bulk portion; the first grounding transistor device being coupled with the switching transistor device; the first grounding transistor device having connection loci permitting electrical coupling with the gate, the source, the drain and the bulk portion of the first grounding transistor device; the source connection locus and the bulk connection locus being coupled in common. (b) Operating the charging circuit in response to the clock signal to periodically apply the supply voltage to charge the boosting capacitor. (c) Operating the switching circuit in response to the clock signal to periodically couple the switching transistor device with the boosting capacitor. (d) Operating the second grounding transistor device in response to the clock signal to periodically effect coupling the first grounding transistor device with the ground locus.

It is, therefore, an object of the present invention to provide an apparatus and method for effecting switching of an input signal by a switching transistor providing improved distortion levels over prior art apparatuses and methods.

Further objects and features of the present invention will be apparent from the following specification and claims when considered in connection with the accompanying drawings, in which like elements are labeled using like reference numerals in the various figures, illustrating the preferred embodiments of the invention.

### BRIEF DESCRIPTION OF THE DRAWINGS

FIG. 1 is an electrical schematic diagram illustrating a prior art bootstrap apparatus for switching of an input signal by a switching transistor.

FIG. 2 is an electrical schematic diagram illustrating a bootstrap apparatus for switching of an input signal by a switching transistor configured according to the teachings of the present invention.

FIG. 3 is an electrical schematic diagram of a representative sample-and-hold circuit employing the bootstrap signal switching apparatus of the present invention.

FIG. 4 is a flow chart illustrating the method of the present invention.

### DETAILED DESCRIPTION OF THE PREFERRED EMBODIMENT

The term “locus” is intended herein to indicate a place, location, locality, locale, point, position, site, spot, volume, juncture, junction or other identifiable location-related zone in one or more dimensions. A locus in a physical apparatus may include, by way of example and not by way of limitation, a corner, intersection, curve, line, area, plane, volume or a portion of any of those features. A locus in an electrical apparatus may include, by way of example and not by way of limitation, a terminal, wire, circuit, circuit trace, circuit board, wiring board, pin, connector, component, collection of components, sub-component or other identifiable location-related area in one or more dimensions. A locus in a flow chart may include, by way of example and not by way of limitation, a juncture, step, site, function, query, response or other aspect, step, increment or an interstice between junctures, steps, sites, functions, queries, responses or other aspects of the flow or method represented by the chart.

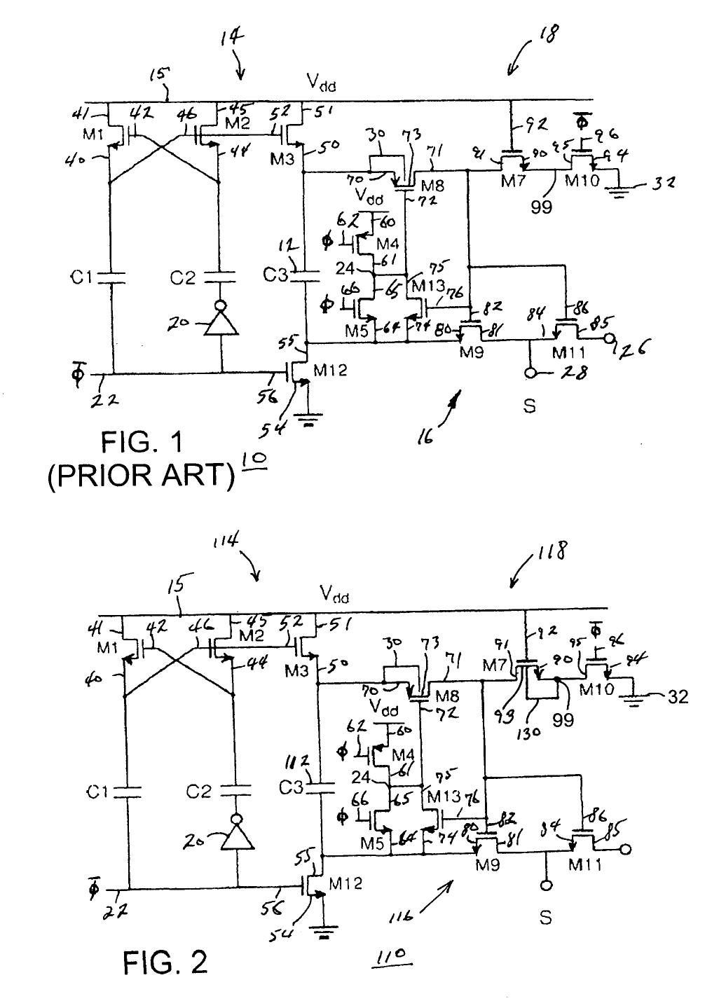

FIG. 1 is an electrical schematic diagram illustrating a prior art bootstrap apparatus for switching of an input signal by a switching transistor. In FIG. 1, a switching apparatus 10, a boosting capacitor 12 a charging circuit 14, a switching circuit 16 and a grounding circuit 18.

Charging circuit 14 includes transistors M1, M2, M3, M12 and capacitors C1, C2, C3. Transistor M1 has a source 40, a drain 41 and a gate 42. Transistor M2 has a source 44, a drain 45 and a gate 46. Transistor M3 has a source 50, a drain 51 and a gate 52. Transistor M12 has a source 54, a drain 44 and a gate 56. An inverter 20 is coupled in series with capacitor C2. Drains 42, 45, 51 are coupled with a voltage supply line 15 providing a supply voltage Vdd. Source 40 is coupled with a clock input locus 22 via capacitor C1. Source 44 is coupled with a clock input locus 22 via capacitor C2 and inverter 20. Gates 46, 52 are coupled with capacitor C1. Gate 42 is coupled with capacitor C2. Source 50 is coupled with capacitor C3 and source 70. Drain 55 is coupled with capacitor C3.

Switching circuit 16 includes Transistors M4, M5, M8, M13, M9 and M11. Transistor M4 has a source 60, a drain 61 and a gate 62. Transistor M5 has a source 64, a drain 65 and a gate 66. Transistor M8 has a source 70, a drain 71 and a gate 72. Transistor M13 has a source 74, a drain 75 and a gate 76. Transistor M9 has a source 80, a drain 81 and a gate 82. Transistor M11 has a source 84, a drain 85 and a gate 86. Transistor M13 is peculiar to the illustrated example and embodiment, but need not be present for the bootstrap action to take place.

Source 60 is coupled to receive supply voltage Vdd. Drain 61 is coupled with drain 65 at a circuit locus 24. Gates 62, 66 are coupled to receive clock signal φ. Gate 72 and drain 75 are also coupled with circuit locus 24. Gates 76, 82, 86 are coupled with drains 71, 91. Sources 64, 74, 80 are coupled with drain 55 of transistor M12.

Transistor M8 has a bulk portion 73. Electrical connection with bulk portion 73 is provided by a bulk connection lead 30 (sometimes referred to as a back gate) coupling bulk portion 73 with the source 70 of transistor M8. By way of illustration and not by way of limitation, the bulk portion of an NMOS transistor may be embodied in a p-well and the bulk portion of a PMOS transistor may be embodied in an n-well.

Transistor M9 is coupled via its drain 81 with the source 84 of transistor M11. Gate 86 of transistor M11 is coupled with gate 82 of transistor M9 and with gate 76 of transistor M13. Drain 85 of transistor M11 is coupled with an output locus 26. An input signal S is provided at a signal input locus 28 coupled with source 84 of transistor M11.

Grounding circuit 18 includes transistors M7, M10. Transistor M7 has a source 90, a drain 91 and a gate 92. Transistor M10 has a source 94, a drain 95 and a gate 96. Source 90 of transistor M7 is coupled with drain 95 of transistor M10. Gate 92 of transistor M7 is coupled with upper voltage supply rail 15. Drain 91 of transistor M7 is coupled with drain 71 of transistor M8, gate 76 of transistor M13, gate 82 of transistor M9 and gate 86 of transistor M11. Gate 96 of transistor M10 is coupled to receive a clock signal φ̅ (i.e., “not φ”). Source 94 of transistor M10 is coupled with a ground locus 32.

Switching apparatus 10 operates using a single phase clock signal φ that turns transistor M11 on and off. During the “off” phase (i.e., transistor M11 is off; not conducting) clock signal φ is low. Transistor M10 receives clock signal φ̅ (i.e., “not φ”) at gate 96 and therefore is on so that ground locus 32 is coupled via transistor M7 (always on because supply voltage Vdd is applied to gate 92) with gate 86 of transistor M11. Transistors M7, M10 therefore discharge gate 86 of transistor M11 to ground locus 32 and transistor M11 does not conduct. During the same clock state (i.e., clock signal φ is low) clock signal φ̅ is applied to gates 52, 56, gating transistors M3, M12 so that supply voltage Vdd is applied across charging capacitor C3, thereby charging capacitor C3. The low clock signal φ is applied to gate 62, turning transistor M4 on (conducting) and turning transistor M5 off (not conducting). This applied supply voltage Vdd to gate 72, keeping transistor M8 turned off (not conducting) thus isolating transistor M11 from the charging voltage Vdd applied to capacitor C3. The low potential provided from ground locus 32 via transistors M10, M7 keeps gate 82 low so that transistor M9 is also turned off (not conducting) thereby further isolating transistor M11 from potential applied across capacitor C3.

During the “on” phase of operation of switching apparatus 10, clock signal φ goes high, and clock signal φ̅ goes low. Transistors M3, M12 are turned off and charging of capacitor C3 is stopped. Charging capacitor C3 acts as a battery across gate 86 and source 84 of transistor M11 during the “on” phase of operation of switching apparatus 10 (i.e., when clock signal φ is high). Transistor M4 is turned off, transistor M5 is turned on, and gate 72 of transistor M8 is pulled low through transistor M5. Transistor M8 is therefore turned on (conducting) and permits charge from charging capacitor C3 to be applied to gate 86 of transistor M11. As a result, both transistors M9, M11 are turned on (conducting). Transistor M9 allows transistor M11 to track input signal S, shifted by voltage Vdd, at input locus 28, and keeps the gate-to-source voltage of transistor M11 substantially constant regardless of the level of input signal S. Connecting body 73 of transistor M8 to its source 70 via bulk connection lead 30 suppresses latch-up by switching apparatus 10.

Transistor M7 is described by Abo and Gray as being a device not functionally necessary but which serves to improve circuit reliability for switching apparatus 10. According to Abo and Gray, transistor M7 reduces Vds (drain-to-source voltage) and Vgd (gate-to-drain voltage) experienced by transistor M10 when clock signal φ is 0 (i.e., when φ is low). Abo and Gray suggest that channel length (a physical dimension of a transistor) of transistor M7 may be increased to further improve its punch-through voltage (i.e., improve its ability to withstand failure to a higher failure, or punch-through, voltage).

The inventors have found that transistor M7 is far from “a device not functionally necessary but which serves to improve circuit reliability” in switching circuit 110. Transistor M7 is connected within switching apparatuses 10 for operation substantially as a dummy switch to aid in performance of transistor M10. It is in this capacity that transistor M7 is always on (conducting) because having gate 92 coupled with voltage supply rail 15 assures that supply voltage Vdd is always applied to gate 92. However, the inventors have discovered that in applications where a large voltage swing is presented by input signal S, transistor M7 can operate as a non-linear resistor feeding a parasitic capacitance existing at a circuit node 99 between source 90 and drain 95 in switching apparatus 10. In such a capacity, transistor M7 can introduce distortion in an otherwise linear charge sharing between capacitor C3 and capacitance at gate 86 of transistor M11.

FIG. 2 is an electrical schematic diagram illustrating a bootstrap apparatus for switching of an input signal by a switching transistor configured according to the teachings of the present invention. In FIG. 2, components are arranged in a circuit substantially similar to switching apparatus 10 (FIG. 1). In order to avoid prolixity, only differences with switching apparatus 10 will be described in connection with FIG. 2. In FIG. 2, a switching apparatus 110 includes a boosting capacitor 112 a charging circuit 114, a switching circuit 116 and a grounding circuit. Boosting capacitor 112, charging circuit 114 and switching circuit 116 are configured in switching circuit 110 substantially as boosting capacitor 12, charging circuit 14 and switching circuit 16 are configured in switching circuit 10 (FIG. 1).

Grounding circuit 118 includes transistors M7, M10. Transistor M7 has a source 90, a drain 91 and a gate 92. Transistor M7 has a bulk portion. Electrical connection with bulk portion 93 is provided by a bulk connection lead 130 (sometimes referred to as a back gate) coupling bulk portion 93 with the source 90 of transistor M7. As is present in switching apparatus 10, transistor M10 has a source 94, a drain 95 and a gate 96. Source 90 of transistor M7 is coupled with drain 95 of transistor M1. Gate 92 of transistor M7 is coupled with upper voltage supply rail 15. Drain 91 of transistor M7 is coupled with drain 71 of transistor M8, gate 76 of transistor M13, gate 82 of transistor M9 and gate 86 of transistor M11. Gate 96 of transistor M10 is coupled to receive a clock signal 0 (i.e., “not φ”). Source 94 of transistor M10 is coupled with a ground locus 32.

In high-speed and high-resolution ADC applications, as well as in other instances when sampling of an analog signal is involved (e.g., optical receivers and data stream slicers), any signal-dependent injection introduced by the switch may cause distortion. Although even-order harmonics can be rejected by employing a differential path front-end sampling, odd-order harmonic rejection solely relies on the linearity of the switch. From the 12 bit level accuracy upward, the distortion requirements (measured by the Spurious Free Dynamic Range; SFDR) by manufacturers may be higher than 80 dB (decibels). This level of distortion can be easily generated by switch non-linearity alone. Newer high-IF (Intermediate Frequency) sampling receiver designs may require linear handling of high-frequency channel variations. Such distortion may be at least partly controlled by minimizing parasitics in a switching device, for example by applying a high voltage on the gate of a switching transistor (e.g., transistor M11; FIG. 1). High resolution of a converter must also rely on high signal range in front of the ADC quantizer cell. This requirement means that the switch must handle ever higher voltages, a contributor to even more parasitics and other causes of distortion.

The inventors have found that electrically connecting bulk portion 93 of transistor M7 with source 90 by bulk connection lead 130 yields an improvement of more than 10 dB in the distortion introduced by switching apparatus 110 over switching apparatus 10 (FIG. 1).

The performance improvement realized with the present invention is mainly a reduction in distortion. After the first-order resistance curvature of transistor M11 has been undone by applying the additional bootstrap voltage (from capacitor C3), distortion still extant in the bootstrap circuitry lies in the residual signal-dependence of the Vgs (gate-to-source voltage) that is imposed on gate 86 of transistor M11. Such a signal-dependence cannot come from the charge stored in the booster capacitor C3 because capacitor C3 is not exposed to input signal S until capacitor C3 is connected across source 84 and gate 86 of transistor M11 when clock signal φ goes high. As described above in connection with switching circuit 10 (FIG. 1), transistor M11 only conducts when clock signal φ is high. When clock signal φ is high, gate voltage VGM11 on gate 86 of transistor M11 is at a level
VGM11S=VS+VBoost, [1]

Where VS is the voltage of input signal S; and
VBoost is a voltage contribution from capacitor C3.

VBoost is substantially equal with voltage stored in capacitor C3. In principle voltage VBoost is linearly attenuated only by capacitive charge-sharing effects. One may observe that voltage at gate 86 is substantially fully modulated by input signal S. Ideally the grounding of capacitor C3 does not perturb the linear charge sharing between capacitor C3 and capacitance at gate 86 of transistor M11. However, transistor M7 may introduce a non linear RC (Resistive-Capacitive) path in parallel with gate capacitance at gate 86, which can modulate final Vgs across gate 86 and source 84, and thereby affecting linearity of operation of switching apparatus 10.

There are tradeoffs in operation involved. The amount of capacitance seen through transistor M7 alters charge sharing between capacitor C3 and gate capacitance at gate 86. This alteration of charge sharing can reduce the additional VBoost provided to gate 86 and disadvantageously affect correction to non-linearity of switching response by transistor M11 provided by switching apparatus 10. Also, variable resistance of transistor M7 affects the extent of the distortion affecting the charge sharing between capacitor C3 and gate capacitance at gate 86.

So long as the RC time constant of transistor M7 is fast enough to end charging of circuit node 99 between source 90 and drain 95, charge sharing between capacitor C3 and gate capacitance at gate 86 is completed by the end of a clock cycle. In that situation, charge sharing between capacitor C3 and gate capacitance at gate 86 is not affected by a non-linear resistance. However, even if a mild non-linearity is contributed from circuit node 99 that does not degrade distortion (e.g., measured as SFDR) appreciably, if charge sharing is not favorable to gate capacitance at gate 86 because of the size of capacitance at node 99, the additional VBoost provided to gate 86 is lowered and distortion worsens.

As a consequence, widening transistor M7 (as suggested by Abo and Gray) to reduce resistance will merely increase parasitic capacitance (according to width of transistor M7) making such a remedy ineffective.

The inventors have found that improving the bulk connection of transistor M7 by shorting bulk 93 with source 90 reduces resistance contributed by transistor M7 and inherently linearizes contribution by transistor M7. This is believed to result because a square root term in a relationship known to those skilled in the art as relating threshold voltage Vth with voltage Vsb between source and bulk of a transistor. The advantage provided by the present invention overcomes increase in capacitance at circuit node 99 by capacitance of bulk 93 of transistor M7. Improved linearity of response of switching apparatus 110 results.

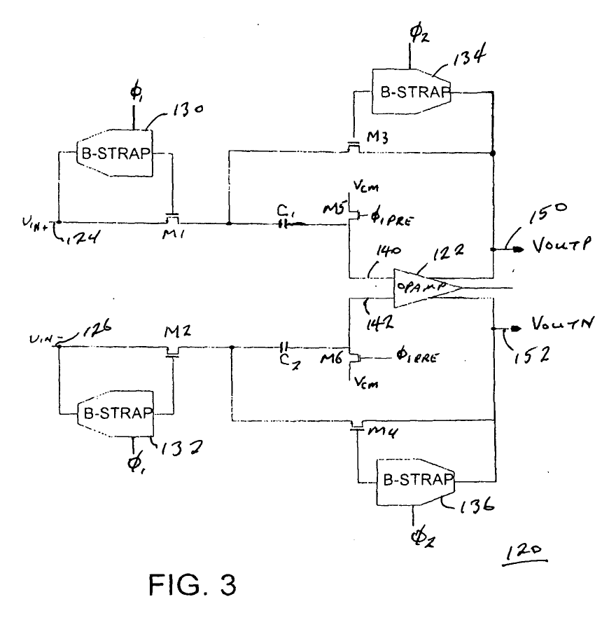

FIG. 3 is an electrical schematic diagram of a representative sample-and-hold circuit employing the bootstrap signal switching apparatus of the present invention. In FIG. 3, a sample-hold apparatus 120 includes an operational amplifier 122 provided with differential signals VIN+ (at an input locus 124), VIN−(at an input locus 126). A bootstrap circuit 130 is coupled to affect input signals switched by a transistor M1 in response to a clock signal φ1. A bootstrap circuit 132 is coupled to affect input signals switched by a transistor M2 in response to clock signal 11.

Switched input signals are provided from transistor M1 via a capacitor C1 to an input locus 140 of operational amplifier 122. Signals presented at input locus 140 are supplemented by a voltage VCM via a transistor M5. Voltage VCM is the common mode voltage having a level substantially equidistant between levels of input signals VIN+, VIN−. Transistor M5 is gated or controlled by a signal φPRE. Signal φPRE is a clock signal just slightly leading clock signal φ1 in time to gate transistor M5 just slightly earlier than clock signal φ1 gates transistor M1, thus ensuring that any charge injection coming from transistor M1 switching to the off state does not perturb the charge stored on the sampling capacitor C1.

Switched input signals are provided from transistor M2 via a capacitor C2 to an input locus 142 of operational amplifier 122. Signals presented at input locus 142 are supplemented by a voltage VCM via a transistor M6. Transistor M6 is gated or controlled by a signal φPRE to that voltage VCM is available to supplement input signals presented at input locus 142.

An output signal VOUTP is presented from operational amplifier 122 at an output locus 150. A bootstrap circuit 134 is coupled to affect feedback signals from output locus 150 switched by a transistor M3 in response to a clock signal φ2, which is out of phase with clock signal φ1. An output signal VOUTN is presented from operational amplifier 122 at an output locus 152. A bootstrap circuit 136 is coupled to affect feedback signals from output locus 152 switched by a transistor M4 in response to clock signal φ2.

Bootstrap circuits 130, 132, 134, 136 are configured according to the teachings of the present invention and may be configured substantially as switching apparatus 110 (FIG. 2).

Not only the voltages driving input switches M1, M2 need to be boosted above input signals VIN+, VIN−. Feedback switches M3, M4 convey the same high voltages from the output loci 150, 152 back onto capacitors C1, C2, as are conveyed by input switches M1, M2. Any non-linearity introduced by feedback switches M3, M4 directly affects linearity of output signals VOUTP, VOUTN.

Sub-optimal prior art performance is obtained when bootstrap circuits configured according to the present invention are applied solely for input switches M1, M2. In contrast, when bootstrap circuits configured according to the present invention are provided for input switches M1, M2 as well as provided for feedback switches M3, M4 (as illustrated in sample-hold apparatus 120) a 10 dB improvement in distortion is manifested over providing bootstrap circuits only for input switches M1, M2.

It is remarkable how the body effect of the switch itself does not introduce major distortion in the system in the illustrated implementation. In simulation, the backgate of transistor M11 (FIG. 1) was switched between ground or a low potential supply locus (open state) and shorted to source 84 (VBS=0 for closed state) without appreciable difference in distortion measured in terms of SFDR.

The inventors have discovered that the invention does not completely suppress the dependence of VGS of transistor M11 from the sinusoidal output signal. However the amplitude of the modulation is lowered enough to abate third-order distortion by at least 10 dB.

The inventors also discovered another reason that the present invention provides less distortion. In prior art switching apparatus 10 (FIG. 1) circuit node 99 is simply grounded and released by transistor M10. Because gate 92 of transistor M7 and the substrate upon which transistor M7 is located (not shown in FIGS. 1, 2) do not see the boosted voltage, the settled levels on source 90 are almost constant, with only slight sinusoidal modulation. Since the backgate voltage of transistor M7 is no longer grounded in switching apparatus 110, the boosted signal seen on drain 91 of transistor M7 strongly affects node 99 through backgate 93 and the modulation is more apparent. This effect affects the linearity of the boosted gate voltage VGM11 for transistor M11, which is impacted by the non-linearity experienced at drain 91 of transistor M7, at least partially eliminating the bulk effect of transistor M7 and finally driving transistor M11 with a more linear, yet still dependent upon voltage of input signal S.

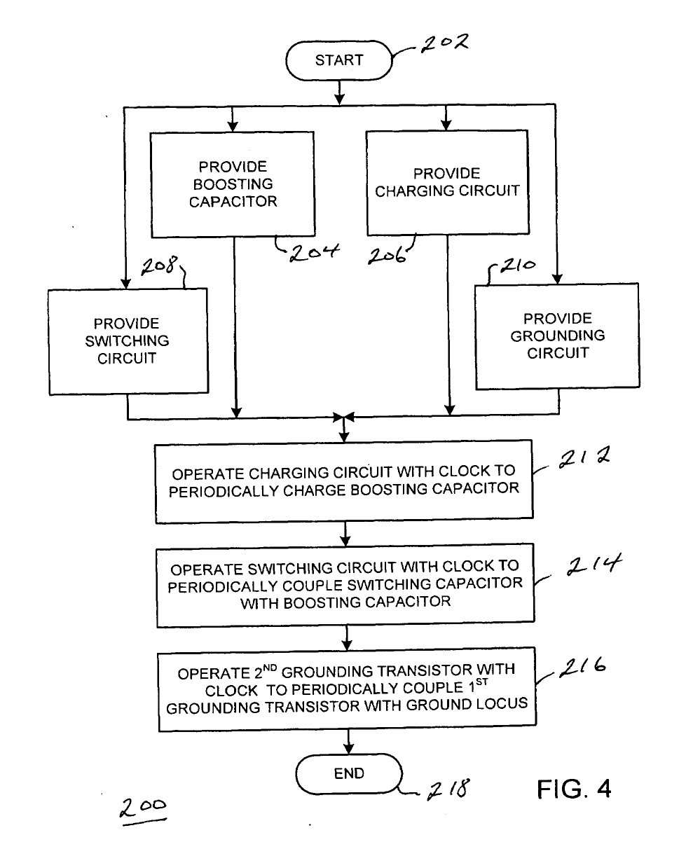

FIG. 4 is a flow chart illustrating the method of the present invention. In FIG. 4, a method 200 for effecting switching of an input signal by a switching transistor device in response to a clock signal begins at a START locus 202. Method 200 continues with the step of, in no particular order: (1) providing a boosting capacitor; as indicated by a block 204; (2) providing a charging circuit coupled with a supply voltage and the boosting capacitor; as indicated by a block 206; (3) providing a switching circuit coupled with the boosting capacitor; as indicated by a block 208; and (4) providing a grounding circuit coupled with the switching transistor device and with a ground locus; as indicated by a block 210. The grounding circuit includes a first grounding transistor device and a second grounding transistor device. The first grounding transistor device has a gate, a source, a drain and a bulk portion. The first grounding transistor device is coupled with the switching transistor device. The first grounding transistor device has connection loci permitting electrical coupling with the gate, the source, the drain and the bulk portion of the first grounding transistor device. The source connection locus and the bulk connection locus are coupled in common.

Method 200 continues with the step of operating the charging circuit in response to the clock signal to periodically apply the supply voltage to charge the boosting capacitor; as indicated by a block 212. Method 200 continues with the step of operating the switching circuit in response to the clock signal to periodically couple the switching transistor device with the boosting capacitor; as indicated by a block 214. Method 200 continues with the step of operating the second grounding transistor device in response to the clock signal to periodically effect coupling the first grounding transistor device with the ground locus as indicated by a block 216. Method 200 terminates at an END locus 218.

The present invention improves distortion of a voltage signal passed through a bootstrap driven switch. Non-linearity of a driving switch is linearized to an extent that manifests 10 dB less distortion, even for input signals having low input frequency.

In designs in which a sampling switch is operated using the present invention, advantages provided by the invention can positively affect jitter and other non-linearities for an entire system. The Signal-to-Noise Ratio (SNR) for an ADC could be improved by using the enhanced slope of a boosted clock signal phase φPRE as illustrated in FIG. 3 being taken from a higher voltage down to a lower voltage or to ground. Such high-to-low transitions must be carried out in as short a time as possible. The present invention provides advantages in faster pull-down transitions, with pull-down devices included within the bootstrap switching circuit.

The present invention is simple to implement. The invention can be included in a preexisting bootstrap circuit block, once enough room is allocate to accommodate an isolated NMOS transistor. In SOI (Silicon On Insulator) technologies equipped with trench isolation, such an additional space requirement is minimal.

The present invention does not require any additional power consumption and actually has a beneficial effect on the reliability of a cascoded device (e.g., transistor M7; FIGS. 1 and 2) because its Vgs (gate-to-substrate voltage) is lowered when using the invention.

It is to be understood that, while the detailed drawings and specific examples given describe preferred embodiments of the invention, they are for the purpose of illustration only, that the apparatus and method of the invention are not limited to the precise details and conditions disclosed and that various changes may be made therein without departing from the spirit of the invention which is defined by the following

I claim:

1. An apparatus for effecting switching of an input signal by a switching transistor device in response to a clock signal; the apparatus comprising:
(a) a boosting capacitor;
(b) a charging circuit coupled with a supply voltage and said boosting capacitor; said charging circuit responding to said clock signal to periodically apply said supply voltage to charge said boosting capacitor;
(c) a switching circuit coupled with said boosting capacitor; said switching circuit responding to said clock signal to periodically couple said switching transistor device with said boosting capacitor; and
(c) a grounding circuit coupled with said switching transistor device and with a ground locus; said grounding circuit including a first grounding transistor device and a second grounding transistor device; said first grounding transistor device having a gate, a source, a drain and a bulk portion; said first grounding transistor device being coupled with said switching transistor device; said first grounding transistor device having connection loci permitting electrical coupling with said gate, said source, said drain and said bulk portion of said first grounding transistor device; said source connection locus and said bulk connection locus being coupled in common; said second grounding transistor device responding to said clock signal to periodically effect coupling said first grounding transistor device with said ground locus.

2. An apparatus for effecting switching of an input signal by a switching transistor device in response to a clock signal as recited in claim 1 wherein said clock signal is provided in at least two phases.

3. An apparatus for effecting switching of an input signal by a switching transistor device in response to a clock signal as recited in claim 1 wherein said clock signal is provided at least a first phase and a second phase; said charging circuit effecting charging said boosting capacitor during said first phase; said switching circuit effecting coupling said switching transistor device with said boosting capacitor during another phase of said at least a first phase and a second phase other than said first phase.

4. An apparatus for effecting switching of an input signal by a switching transistor device in response to a clock signal as recited in claim 2 wherein said charging circuit effects charging said boosting capacitor during a first phase of said at least two phases; said switching circuit effecting coupling said switching transistor device with said boosting capacitor during a second phase of said at least two phases.

5. An apparatus for effecting conversion of a continuous-time analog input signal to a sampled discrete-time analog output signal in response to a clock signal; the apparatus comprising:
(a) a switching transistor; said switching transistor receiving said input signal at a first locus and presenting said output signal at an output locus;
(b) a boosting capacitor;
(c) a charging circuit coupled with a supply voltage and said boosting capacitor; said charging circuit responding to said clock signal to periodically apply said supply voltage to charge said boosting capacitor;
(d) a switching circuit coupled with said boosting capacitor; said switching circuit responding to said clock signal to periodically couple said switching transistor with said boosting capacitor; and
(e) a grounding circuit coupled with said switching transistor and with a ground locus; said grounding circuit including a first grounding transistor and a second grounding transistor; said first grounding transistor having a gate, a source, a drain and a bulk portion; said first grounding transistor being coupled with said switching transistor; said first grounding transistor having connection loci permitting electrical coupling with said gate, said source, said drain and said bulk portion; said source connection locus and said bulk connection locus being coupled in common; said second grounding transistor responding to said clock signal to periodically effect coupling said first grounding transistor with said ground locus.

6. An apparatus for effecting conversion of a continuous-time analog input signal to a sampled discrete-time analog output signal in response to a clock signal as recited in claim 5 wherein said clock signal is provided in at least two phases.

7. An apparatus for effecting conversion of a continuous-time analog input signal to a sampled discrete-time analog output signal in response to a clock signal as recited in claim 5 wherein said clock signal is provided at least a first phase and a second phase; said charging circuit effecting charging said boosting capacitor during said first phase; said switching circuit effecting coupling said switching transistor device with said boosting capacitor during another phase of said at least a first phase and a second phase other than said first phase.

8. An apparatus for effecting conversion of a continuous-time analog input signal to a sampled discrete-time analog output signal in response to a clock signal as recited in claim 6 wherein said charging circuit effects charging said boosting capacitor during a first phase of said at least two phases; said switching circuit effecting coupling said switching transistor device with said boosting capacitor during a second phase of said at least two phases.

9. A method for effecting switching of an input signal by a switching transistor device in response to a clock signal; the method comprising the steps of:
(a) in no particular order:
(1) providing a boosting capacitor;
(2) providing a charging circuit coupled with a supply voltage and said boosting capacitor;
(3) providing a switching circuit coupled with said boosting capacitor; and
(4) providing a grounding circuit coupled with said switching transistor device and with a ground locus; said grounding circuit including a first grounding transistor device and a second grounding transistor device; said first grounding transistor device having a gate, a source, a drain and a bulk portion; said first grounding transistor device being coupled with said switching transistor device; said first grounding transistor device having connection loci permitting electrical coupling with said gate, said source, said drain and said bulk portion of said first grounding transistor device; said source connection locus and said bulk connection locus being coupled in common;
(b) operating said charging circuit in response to said clock signal to periodically apply said supply voltage to charge said boosting capacitor;
(c) operating said switching circuit in response to said clock signal to periodically couple said switching transistor device with said boosting capacitor; and
(d) operating said second grounding transistor device in response to said clock signal to periodically effect coupling said first grounding transistor device with said ground locus.

10. A method for effecting switching of an input signal by a switching transistor device in response to a clock signal as recited in claim 9 wherein said clock signal is provided in at least two phases.

11. A method for effecting switching of an input signal by a switching transistor device in response to a clock signal as recited in claim 9 wherein said clock signal is provided at least a first phase and a second phase; said charging circuit effecting charging said boosting capacitor during said first phase; said switching circuit effecting coupling said switching transistor device with said boosting capacitor during another phase of said at least a first phase and a second phase other than said first phase.

12. A method for effecting switching of an input signal by a switching transistor device in response to a clock signal as recited in claim 10 wherein said charging circuit effects charging said boosting capacitor during a first phase of said at least two phases; said switching circuit effecting coupling said switching transistor device with said boosting capacitor during a second phase of said at least two phases.
